(19) United States
(12) Patent Application Publication
(10) Pub. No.: US 2026/0323992 A1
(43) Pub. Date: Oct. 15, 2026

(54) SEMICONDUCTOR DEVICE, ELECTRONIC APPARATUS INCLUDING THE SAME, AND METHOD OF MANUFACTURING THE SEMICONDUCTOR DEVICE

(71) Applicant: Samsung Electronics Co., Ltd., Suwon-si (KR)

(72) Inventors: Hajun SUNG, Suwon-si (KR); Yongyoung PARK, Suwon-si (KR); Kiyeon YANG, Suwon-si (KR); Younjin JANG, Suwon-si (KR); Minwoo CHOI, Suwon-si (KR)

(73) Assignee: Samsung Electronics Co., Ltd., Suwon-si (KR)

(21) Appl. No.: 19/425,293

(22) Filed: Dec. 18, 2025

(30) Foreign Application Priority Data
Apr. 11, 2025 (KR) 10-2025-0047689

(51) Int. Cl. H10D 30/67; H10D 30/01

(52) U.S. Cl. CPC H10D 30/6706; H10D 30/031; H10D 30/6755

(57) ABSTRACT

Provided are semiconductor devices, electronic apparatuses including the semiconductor device, and methods of manufacturing the semiconductor device. The semiconductor device includes a channel including a first surface and a second surface opposing the first surface, a source electrode electrically connected to the channel, a drain electrode electrically connected to the channel and being apart from the source electrode, a gate insulating layer above the channel, a gate electrode on the gate insulating layer, and a reduction-inducing layer on at least one selected from the first surface and the second surface of the channel.

### CROSS-REFERENCE TO RELATED APPLICATION

This application is based on and claims priority under 35 U.S.C. § 119 to Korean Patent Application No. 10-2025-0047689, filed on Apr. 11, 2025, in the Korean Intellectual Property Office, the disclosure of which is incorporated by reference herein in its entirety.

### BACKGROUND

### 1. Field

Some example embodiments relate to semiconductor devices including a p-type channel, electronic apparatuses including the semiconductor device, and/or methods of manufacturing the semiconductor device.

### 2. Description of the Related Art

Oxide semiconductors that exhibit relatively high electrical performance and are used in semiconductor devices are often n-type semiconductors capable of relatively efficiently transporting electrons at room temperature. In contrast, the development of p-type semiconductors capable of transporting holes may face some limitations in their applicability across various fields. InGaZnO, which is an example of an n-type semiconductor, is relatively widely used. For example, InGaZnO may be applied to backplane transistors that drive organic light-emitting diode (OLED) displays.

Materials such as SnO have been studied as p-type oxide semiconductors. However, SnO exhibits lower hole field-effect mobility and/or a lower ON/OFF current ratio than n-type oxide semiconductors. Accordingly, research on p-type oxide semiconductors with improved electrical properties is desired to be conducted for applications in various semiconductor devices.

### SUMMARY

Some example embodiments of the disclosure provide semiconductor devices including a reduction-inducing layer on a channel.

Some example embodiments of the disclosure provide electronic apparatuses including a semiconductor device in which a reduction-inducing layer is provided on a channel.

Some example embodiments of the disclosure methods of manufacturing a semiconductor device in which a reduction-inducing layer is provided on a channel.

Additional aspects will be set forth in part in the description which follows and, in part, will be apparent from the description, or may be learned by practice of the presented embodiments of the disclosure.

According to an example embodiment of the disclosure, a semiconductor device includes a channel including a first surface and a second surface opposing the first surface, a source electrode electrically connected to the channel, a drain electrode electrically connected to the channel and being apart from the source electrode, a gate insulating layer above the channel, a gate electrode on the gate insulating layer, and a reduction-inducing layer on at least one selected from the first surface and the second surface of the channel, wherein the reduction-inducing layer includes M or MO, and M includes at least one selected from Ti, Sc, Ce, Si, and V.

The channel may be a p-type channel.

The channel may include tellurium oxide.

The channel further may include at least one selected from S, Se, In, Sn, Cu, and Ge.

The channel may include TeₐO_{b} where a+b=100, 70≤a≤95, and 5≤b≤30.

The channel may be in an oxygen-deficient state.

A first direction defined from the source electrode toward the drain electrode may be a vertical direction of the semiconductor device, and length directions of the channel, the gate insulating layer, and the gate electrode may be parallel to the first direction.

The channel may further include a bottom portion in contact with the source electrode, a first vertical extension portion extending from an end of the bottom portion in a direction perpendicular to the source electrode, and a second vertical extension portion extending from another end of the bottom portion in the direction perpendicular to the source electrode.

The channel, the gate insulating layer, and the gate electrode may be arranged in a concentric shape, the gate electrode may include a first gate electrode and a second gate electrode that are apart from each other, and a spacer may be between the first gate electrode and the second gate electrode.

The channel may include a plurality of channels and may have a multi-bridge structure in which the plurality of channels are each in contact with the source electrode and the drain electrode and are stacked apart from each other in a direction away from a substrate.

According to an example embodiment of the disclosure, an electronic apparatus includes a host, a memory device including at least one semiconductor device, and a memory controller configured to control the memory device in response to a request from the host for at least one selected from a first operation of reading data from the memory device and a second operation of writing data to the memory device, The at least one semiconductor device includes a channel including a first surface and a second surface opposing the first surface, a source electrode electrically connected to the channel, a drain electrode electrically connected to the channel and being apart from the source electrode, a gate insulating layer above the channel, a gate electrode on the gate insulating layer, and a reduction-inducing layer on at least one selected from the first surface and the second surface of the channel, wherein the reduction-inducing layer includes M or MO, and M includes at least one selected from Ti, Sc, Ce, Si, and V.

According to an example embodiment of the disclosure, a method of manufacturing a semiconductor device includes forming a channel on a substrate, forming a source electrode and a drain electrode apart from each other on the channel, forming a reduction-inducing layer on the channel, forming a gate insulating layer on the reduction-inducing layer, and forming a gate electrode on the gate insulating layer, wherein the reduction-inducing layer includes M or MO, and the M includes at least one selected from Ti, Sc, Ce, Si, and V.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view illustrating a semiconductor device according to an example embodiment;

FIG. 2 is a graph illustrating a transfer curve when the oxygen content of a TeₐO_{b} channel is 29 at % in a semiconductor device according to an example embodiment;

FIG. 3 is a graph illustrating a transfer curve when the oxygen content of a TeₐO_{b} channel is 24 at % in a semiconductor device according to an example embodiment;

FIG. 4 is a graph illustrating a transfer curve when the oxygen content of a TeₐO_{b} channel is 19 at % in a semiconductor device according to an example embodiment;

FIG. 5 is a graph illustrating the distribution of oxide formation energy and electronegativity of materials included in a reduction-inducing layer of a semiconductor device according to an example embodiment;

FIG. 6 is a view illustrating out-diffusion of oxygen from a channel by a reduction-inducing layer in a semiconductor device according to an example embodiment;

FIG. 7 is a view illustrating an example in which a reduction-inducing layer is provided under a channel in a semiconductor device according to an example embodiment;

FIGS. 8, 9, and 10 are views illustrating examples of semiconductor devices having a vertical channel structure;

FIG. 11 is a horizontal cross-sectional view schematically illustrating a memory cell string structure of a memory device according to an example embodiment;

FIG. 12 is a vertical cross-sectional view illustrating the memory cell string structure depicted in FIG. 11;

FIG. 13 is a view illustrating a semiconductor device having a multi-channel structure, according to an example embodiment;

FIGS. 14A and 14B are views illustrating a method of manufacturing a semiconductor device, according to an example embodiment;

FIG. 15 illustrates a memory device to which a semiconductor device according to an example embodiment is applied;

FIG. 16 is a view illustrating an equivalent circuit of a memory device according to an example embodiment;

FIG. 17 is a conceptual view schematically illustrating a device architecture applicable to an electronic apparatus;

FIG. 18 is a block diagram illustrating a memory system according to an example embodiment; and

FIG. 19 is a block diagram illustrating a neuromorphic apparatus and an external device connected thereto, according to an example embodiment.

### DETAILED DESCRIPTION

Reference will now be made in detail to example embodiments, examples of which are illustrated in the accompanying drawings. In this regard, the present example embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “one of,” “one or more of,” “any one of, “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, semiconductor devices, electronic apparatuses including the semiconductor devices, and methods of manufacturing the semiconductor devices will be described according to various example embodiments with reference to the accompanying drawings. In the drawings, like reference numbers refer to like elements, and the size of each element may be exaggerated for clarity of illustration. It will be understood that although terms such as “first” and “second” may be used herein to describe various components, these components should not be limited by these terms. These terms are only used to distinguish one element from another.

As used herein, singular forms may include plural forms as well unless the context clearly indicates otherwise. It will be further understood that the terms “comprises,” “comprising,” “includes,” and/or “including” used herein specify the presence of stated features or elements, but do not preclude the presence or addition of one or more other features or elements. In the drawings, the size or thickness of each element may be exaggerated for clarity of illustration. Furthermore, it will be understood that when a material layer is referred to as being “on” or “above” a substrate or another layer, it may be directly on the substrate or the other layer, or intervening layers may also be present. Furthermore, in the following example embodiments, a material included in each layer is an example, and another material may be used in addition to or instead of the material.

In the disclosure, terms such as “unit” or “module” may be used to denote a unit that has at least one function or operation and is implemented with hardware, software, or a combination of hardware and software.

Specific executions described herein are merely examples and do not limit the scope of the disclosure in any way. For simplicity of description, other functional aspects of conventional electronic configurations, control systems, software and the systems may be omitted. Furthermore, line connections or connection members between elements depicted in the drawings represent functional connections and/or physical or circuit connections by way of example, and in actual applications, they may be replaced or embodied as various additional functional connections, physical connections or circuit connections.

An element referred to with the definite article or a demonstrative pronoun may be construed as the element or the elements even though it has a singular form.

Operations of a method may be performed in appropriate order unless explicitly described in terms of order or described to the contrary. In addition, examples or terms (for example, “such as” and “etc.”) are used for the purpose of description and are not intended to limit the scope of the disclosure unless defined by the claims.

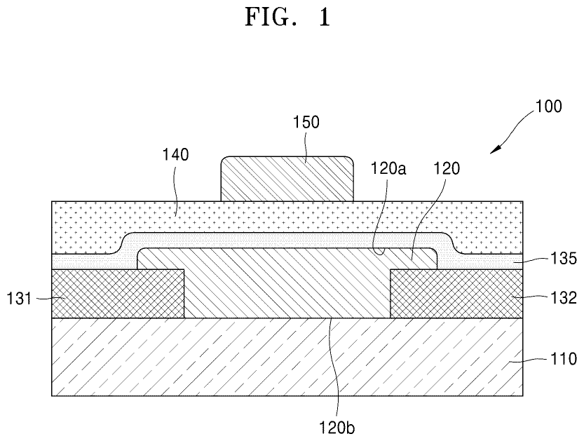

FIG. 1 schematically illustrates a semiconductor device 100 according to an example embodiment.

The semiconductor device 100 includes a substrate 110, a channel 120 provided on the substrate 110, a source electrode 131 electrically connected to the channel 120, a drain electrode 132 electrically connected to the channel 120, a gate insulating layer 140 provided above the channel 120, and a gate electrode 150 provided on the gate insulating layer 140. The channel 120 may include a first surface 120a and a second surface 120b that opposes the first surface 120a. A reduction-inducing layer 135 may be provided on at least one selected from the first surface 120a and the second surface 120b. FIG. 1 illustrates an example in which the reduction-inducing layer 135 is provided on the first surface 120a of the channel 120. That is, the reduction-inducing layer 135 may be provided between the channel 120 and the gate insulating layer 140. The reduction-inducing layer 135 may include a material having lower oxide formation energy than the channel 120. Thus, the reduction-inducing layer 135 may induce oxygen out-diffusion from the channel 120, thereby controlling the oxygen content of the channel 120. The reduction-inducing layer 135 may include M or MO, where M may include at least one selected from Ti, Sc, Ce, Si, and V. Here, O refers to oxygen.

The source electrode 131 and the drain electrode 132 may be arranged apart from each other. The channel 120 may extend to portions of upper surfaces of the source electrode 131 and the drain electrode 132. However, the structure of the channel 120 is not limited thereto. The semiconductor device 100 may be applied to a transistor having a planar channel structure.

The substrate 110 may be an insulating substrate, or a semiconductor substrate having an insulating layer formed on a surface thereof. In some example embodiments, the substrate 110 may be a semiconductor substrate. The semiconductor substrate may include, for example, Si, Ge, SiGe, or a Group III-V semiconductor material. The substrate 110 may be, for example, a silicon substrate having a silicon oxide layer formed on a surface thereof, but is not limited thereto.

The channel 120 may be a p-type channel. The channel 120 may include, for example, tellurium (Te) and oxygen (O). The channel 120 may include TeₐO_{b} (a+b=100, 70≤a≤95, and 5≤b≤30). The channel 120 may further include at least one selected from S, Se, In, Sn, Cu, and Ge. The channel 120 may include a single tellurium oxide layer, or may have a structure in which Te layers and TeO layers are alternately stacked. The channel 120 may have a thickness in a range of about 1 nm to about 100 nm. In addition, the channel 120 may have an amorphous structure.

The source electrode 131 and the drain electrode 132 may include a metal material. The source electrode 131 and the drain electrode 132 may include at least one selected from W (tungsten), Co (cobalt), Ni (nickel), Fe (iron), Ti (titanium), Mo (molybdenum), Cr (chromium), Zr (zirconium), Hf (hafnium), Nb (niobium), Ta (tantalum), Ag (silver), Au (gold), Al (aluminum), Cu (copper), Sb (antimony), V (vanadium), Ru (ruthenium), Pt (platinum), Zn (zinc), and Mg (magnesium). In some example embodiment, the source electrode 131 and the drain electrode 132 may include a nitride including at least one of the listed materials. The source electrode 131 and the drain electrode 132 may include, for example, at least one selected from W, TiN, Mo, MoN, Ru, and TiSiN. The source electrode 131 and the drain electrode 132 may include, for example, zinc (Zn) in a content of 10 at % or less. Here, the Zn content may refer to the atomic ratio of Zn to all metal elements included in the source electrode 131, excluding oxygen.

The gate electrode 150 may include at least one selected from metal, metal nitride, and transparent conductive oxide (TCO). The gate insulating layer 140 may include an oxide including at least one selected from hafnium (Hf), zirconium (Zr), aluminum (Al), and silicon (Si). When the semiconductor device 100 is a component of a memory cell, the gate electrode 150 may be a region of a word line.

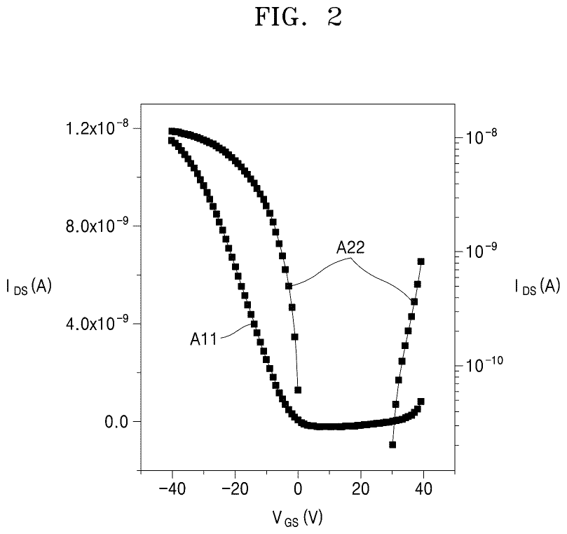

FIGS. 2, 3, and 4 illustrate transfer curves of a semiconductor device for different oxygen contents of a TeₐO_{b} channel 120.

FIG. 2 illustrates a transfer curve when the oxygen content of the TeₐO_{b} channel 120 is 29 at %. When the TeₐO_{b} channel 120 is a Te₇₁O₂₉ channel, the semiconductor device is in an on-current state within a range in which V_{GS} has a negative value, indicating p-type semiconductor characteristics. A curve A11 is a linear-scale curve, and a curve A22 is a log-scale curve.

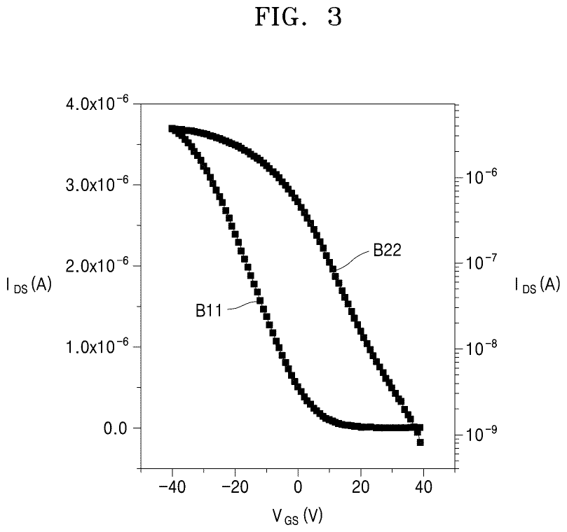

FIG. 3 illustrates a transfer curve when the oxygen content of the TeₐO_{b} channel 120 is 24 at %. When the TeₐO_{b} channel 120 is a Te₇₆O₂₄ channel, the semiconductor device is in an on-current state within a range in which V_{GS} has a negative value, indicating p-type semiconductor characteristics. A curve B11 is a linear-scale curve, and a curve B22 is a log-scale curve.

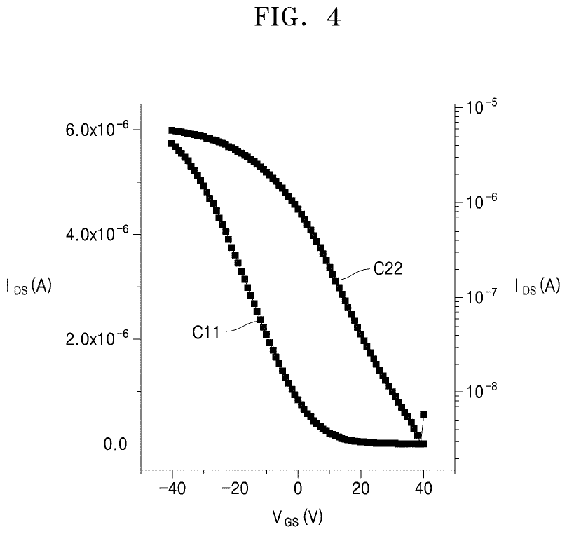

FIG. 4 illustrates a transfer curve when the oxygen content of the TeₐO_{b} channel 120 is 19 at %. When the TeₐO_{b} channel 120 is a Te₈₁O₁₉ channel, the semiconductor device is in an on-current state within a range in which V_{GS} has a negative value, indicating p-type semiconductor characteristics. A curve C11 is a linear-scale curve, and a curve C22 is a log-scale curve.

Referring to FIGS. 2, 3, and 4, as the oxygen content decreases and the tellurium content increases in the TeₐO^{b} channel 120, on-current increases. In addition, as the oxygen content of the TeₐO_{b} channel 120 decreases, mobility and transconductance increase, resulting in improved electrical p-type channel characteristics.

As described above, the semiconductor device 100 of the example embodiment includes TeₐO_{b} (a+b=100, 70≤a≤95, and 5≤b≤30), thereby implementing a p-type channel and exhibiting a relatively large on-current, relatively high transconductance, and/or relatively high mobility.

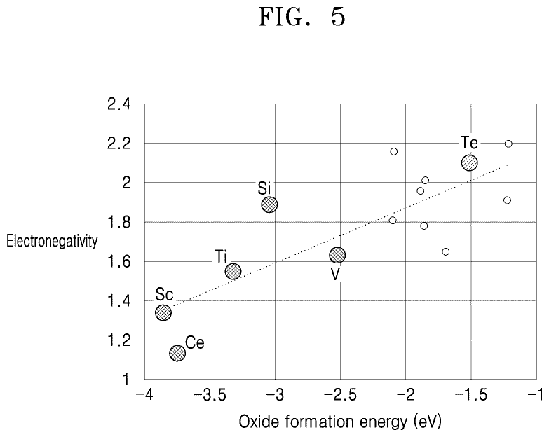

FIG. 5 is a graph illustrating distribution of oxide formation energy and electronegativity of materials included in the reduction-inducing layer 135 of the semiconductor device 100, according to an example embodiment.

The following table shows the oxide formation energies of materials included in the reduction-inducing layer 135. For reference, the oxide formation energy of TeO₂ included in the channel 120 is −1.5 eV.

### Table 1

TABLE 1

| Materials | Oxide formation energy |
|---|---|
| TiO₂ | −3.32 |
| SiO₂ | −3.04 |
| V₂O₅ | −2.52 |
| Sc₂O₃ | −3.86 |
| Ce₂O₃ | −3.76 |

The reduction-inducing layer 135 may include M or MOₓ, and M may have lower electronegativity and lower oxide formation energy than a material included in the channel 120. M may include at least one selected from Ti, Sc, Ce, Si, and V. M may include at least one selected from Ti, Sc, Ce, Si, and V having lower oxide formation energy than Te included in the channel 120. Because the reduction-inducing layer 135 has lower oxide formation energy than the channel 120, the reduction-inducing layer 135 may reduce oxygen in the channel 120 during an annealing process, thereby bringing the channel 120 into an oxygen-deficient state. That is, the channel 120 may have an oxygen-deficient composition in terms of chemical stoichiometry. Chemical stoichiometry represents the quantitative relationships in chemical reactions. Because each chemical reaction involves the recombination of individual molecules in a reaction system according to a specific pattern determined by the reaction, the amounts of substances involved in a reaction may have proportional relationships. The content of oxygen in the channel 120 may be less than a value determined by chemical stoichiometry. When the content of oxygen in the channel 120 including tellurium oxide is deficient, on-current, which is one of p-type semiconductor characteristics, may increase. In addition, the channel 120 may have an amorphous structure.

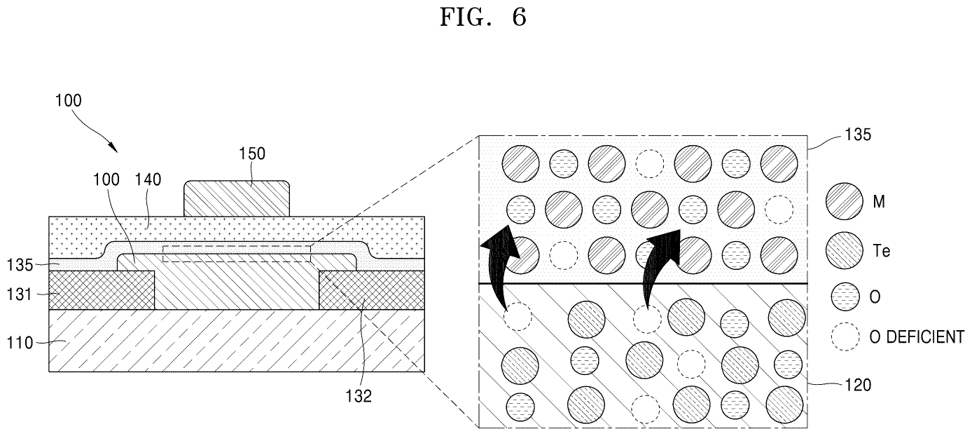

FIG. 6 shows diffusion of oxygen from the channel 120 to the reduction-inducing layer 135. Because the channel 120 is reduced by the reduction-inducing layer 135 including a material with relatively low oxide formation energy, the channel 120 may be oxygen-deficient.

The semiconductor device 100 of the example embodiment may implement a p-type channel and increase on-current by controlling the oxygen content of the channel 120 through the reduction-inducing layer 135.

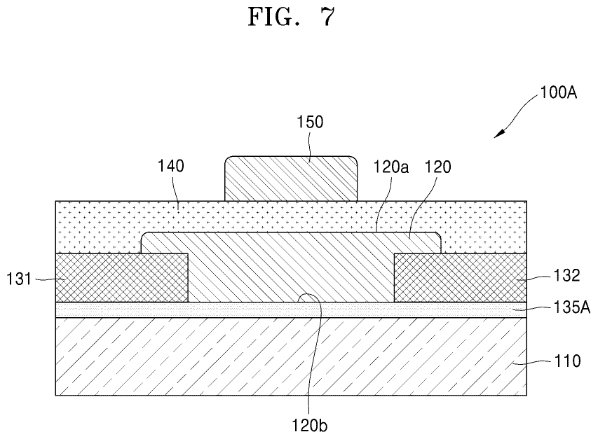

FIG. 7 illustrates an example in which a reduction-inducing layer 135A is provided below a channel 120. In FIG. 7, elements denoted with the same reference numerals as those in FIG. 1 are substantially the same as those described with reference to 1, and thus, descriptions thereof may be omitted here.

In a semiconductor device 100A, the reduction-inducing layer 135A may be provided on a second surface 120b of the channel 120. That is, the reduction-inducing layer 135A may be provided between a substrate 110 and the channel 120. The reduction-inducing layer 135A may be in direct contact with the channel 120 without the interposition of another layer. However, example embodiments are not limited thereto. For example, reduction-inducing layers 135A may be provided on a first surface 120a of the channel and the second surface 120b of the channel 120, respectively.

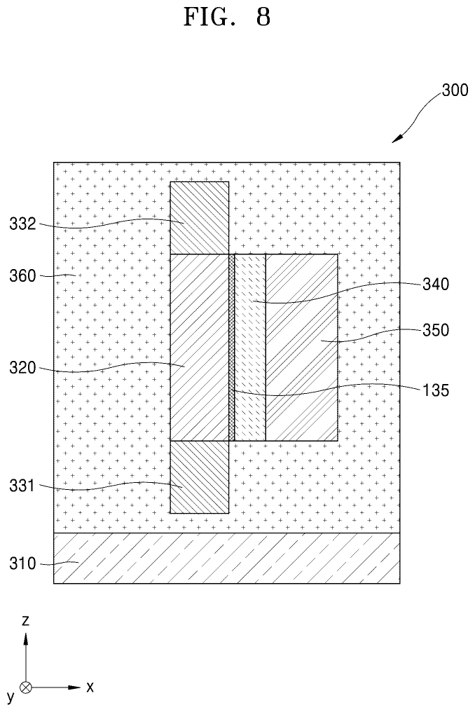

FIG. 8 illustrates a semiconductor device 300 according to another example embodiment.

Referring to FIG. 8, the semiconductor device 300 includes a substrate 310, a source electrode 331 provided above the substrate 310, a drain electrode 332 provided apart from the source electrode 331, and a channel 320 provided between the source electrode 331 and the drain electrode 332. A reduction-inducing layer 135 may be provided on a side of the channel 320.

The channel 320 may include TeₐO_{b} (a+b=100, 70≤a≤95, and 5≤b≤30). The channel 320 may further include at least one selected from S, Se, In, Sn, Cu, and Ge. The channel 320 may include a single tellurium oxide layer or may have a structure in which Te layers and TeO layers are alternately stacked.

The source electrode 331 and the drain electrode 332 may be apart from each other in a direction (z-direction) perpendicular to the substrate 310. The source electrode 331, the channel 320, and the drain electrode 332 may be arranged in a line in the direction (z-direction) perpendicular to the substrate 310. The source electrode 331, the channel 320, and the drain electrode 332 may be sequentially arranged without any layer therebetween. The source electrode 331, the channel 320, and the drain electrode 332 may have the same width. The length direction of the channel 320 may be parallel to the direction (z-direction) perpendicular to the substrate 310 (z-direction). Herein, the length direction of an element refers to a direction in which the element is longer than in other directions in the drawings. The semiconductor device 300 may be applied to a vertical channel transistor (VCT).

A gate electrode 350 may be provided at a side of the channel 320. A gate insulating layer 340 may be provided between the channel 320 and the gate electrode 350. FIG. 8 illustrates an example in which the reduction-inducing layer 135 is provided between the channel 320 and the gate electrode 350. However, the reduction-inducing layer 135 may be provided on the other side of the channel 320, or reduction-inducing layers 135 may be provided on both sides of the channel 320, respectively. The length direction of the gate electrode 350 may be parallel to the direction (z-direction) perpendicular to the substrate 310. The channel 320, the gate insulating layer 340, and the gate electrode 350 may be arranged in a line in a direction (x-direction) parallel to the substrate 310. A mold insulating layer 360 may be provided on the substrate 310 to fill an empty space. The source electrode 331 may be provided apart from the substrate 310 due to the mold insulating layer 360.

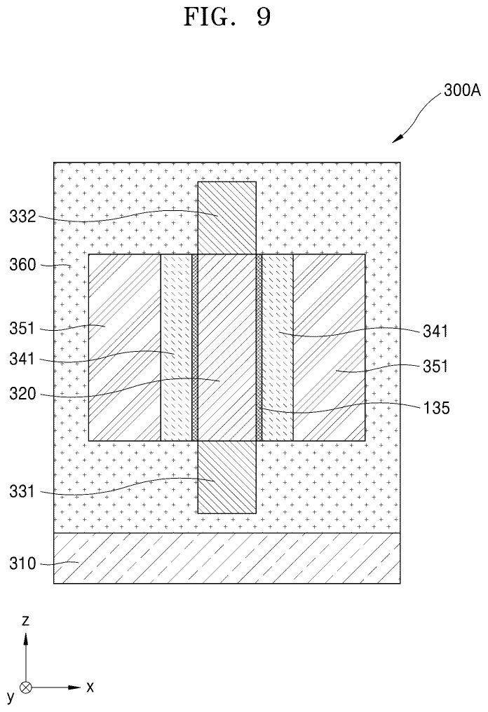

FIG. 9 illustrates a semiconductor device 300A according to another example. In FIG. 9, elements denoted with the same reference numerals as those in FIG. 8 have substantially the same structures and operational effects as those described with reference to FIG. 8, and thus, descriptions thereof may be omitted here.

The semiconductor device 300A includes a source electrode 331, a channel 320, and a drain electrode 332 that are arranged in a direction (z-direction) perpendicular to a substrate 310. A gate insulating layer 341 may be provided around the channel 320, and a gate electrode 351 may be provided around the gate insulating layer 341. A reduction-inducing layer 135 may be provided between the channel 320 and the gate insulating layer 341. Because the gate electrode 351 is provided around the channel 320, a mutually-facing area between the channel 320 and the gate electrode 351 may increase, and short channel effects may be reduced. The semiconductor device 300A may be applied to a gate-all-around (GAA) transistor.

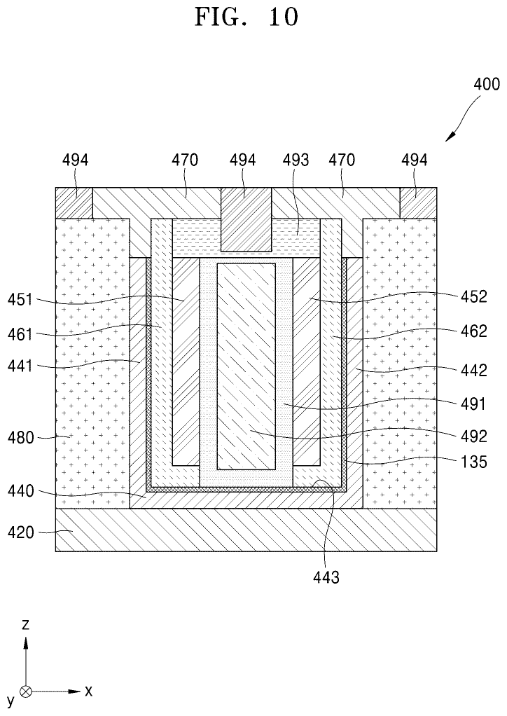

FIG. 10 illustrates a semiconductor device 400 according to another example embodiment.

Referring to FIG. 10, the semiconductor device 400 may include a source electrode 420 and a channel 440 provided on the source electrode 420. The channel 440 may include TeₐO_{b} (a+b=100, 70≤a≤95, and 5≤b≤30). The channel 440 may further include at least one selected from S, Se, In, Sn, Cu, and Ge. The channel 440 may include a single tellurium oxide layer or have a structure in which Te layers and TeO layers are alternately stacked.

The channel 440 may have a U-shaped cross-sectional structure. The channel 440 may include a bottom portion 443 connected to the source electrode 420, a first vertical extension portion 441 extending from an end of the bottom portion 443 in a direction (z-direction) perpendicular to the source electrode 420, and a second vertical extension portion 442 extending from the other end of the bottom portion 443 in the direction (z-direction) perpendicular to the source electrode 420. A reduction-inducing layer 135 may be provided inside the channel 440. In addition, although not specifically illustrated, another reduction-inducing layer may be provided on an outer side of the channel 440. The reduction-inducing layer 135 may have a U-shaped cross-sectional structure corresponding to the shape of the channel 440.

A first gate electrode 451 may be provided apart from the first vertical extension portion 441, and a second gate electrode 452 may be provided apart from the second vertical extension portion 442. A first gate insulating layer 461 may be provided between the first vertical extension portion 441 and the first gate electrode 451, and a second gate insulating layer 462 may be provided between the second vertical extension portion 442 and the second gate electrode 452.

At least one selected from the first gate electrode 451 and the second gate electrode 452 may extend in a second horizontal direction (y-direction). The first gate electrode 451 and the second gate electrode 452 may be apart from each other. At least one selected from the first gate electrode 451 and the second gate electrode 452 may form a word line (WL). An electrical signal input to the first gate electrode 451 may not be the same as an electrical signal input to the second gate electrode 452. The first gate electrode 451 may control the first vertical extension portion 441 of the channel 440, and the second gate electrode 452 may control the second vertical extension portion 442 of the channel 440.

An insulating liner 491 may be provided between the first gate electrode 451 and the second gate electrode 452 that are provided apart from each other. The insulating liner 491 may be conformally provided on mutually-facing sidewalls of the first and second gate electrodes 451 and 452, and/or on an upper surface of the channel 440. The insulating liner 491 may have an upper surface on the same plane as upper surfaces of the first and second gate electrodes 451 and 452. The insulating liner 491 may include, for example, silicon nitride. A buried insulating layer 492 may be provided on the insulating liner 491 to fill a space between the first gate electrode 451 and the second gate electrode 452. The buried insulating layer 492 may include, for example, silicon oxide. An upper insulating layer 493 may be provided on the upper surfaces of the first and second gate electrodes 451 and 452, and/or on the buried insulating layer 492. An upper surface of the upper insulating layer 493 may be at the same level as an upper surface of a mold insulating layer 480.

A drain electrode 470 may be provided above the channel 440. The drain electrode 470 may serve as a landing pad. The drain electrode 470 may include a left drain electrode and a right drain electrode. The left drain electrode 470 may be electrically connected to the first vertical extension portion 441. The right drain electrode 470 may be electrically connected to the second vertical extension portion 442. The left and right drain electrodes may not be electrically connected to each other. The drain electrode 470 may include an upper portion and a lower portion. The upper portion of the drain electrode 470 may be higher than the upper surface of the mold insulating layer 480. The lower portion of the drain electrode 470 may be provided in a drain electrode recess defined between the mold insulating layer 480 and the upper insulating layer 493. In an example embodiment, the upper portion of the drain electrode 470 may have a first width W1 in a first horizontal direction (x-direction), the lower portion of the drain electrode 470 may have a second width w2 in the first horizontal direction (x-direction), and the second width W2 may be less than the first width W1. The lower portion of the drain electrode 470 may be provided in the drain electrode recess, and the upper portion of the drain electrode 470 may have a bottom surface provided on the upper surfaces of the mold insulating layer 480 and the upper insulating layer 493, above the lower portion of the drain electrode 470. Therefore, the drain electrode 470 may have a T-shaped vertical cross-section. A bottom surface of the lower portion of the drain electrode 470 may be in contact with an upper surface of a corresponding one of the first vertical extension portion 441 and an upper surface of the second vertical extension portion 442. Sidewalls of the lower portion of the drain electrode 470 may be aligned with both sidewalls of the first vertical extension portion 441 and both sidewalls of the second vertical extension portion 442. The bottom surface of the lower portion of the drain electrode 470 may be positioned at a level higher than the upper surface of the first gate electrode 451 and/or the upper surface of the second gate electrode 452, and portions of the sidewalls of the lower portion of the drain electrode 470 may be covered by the first gate insulating layer 461 and/or the second gate insulating layer 462. A drain electrode insulating layer 494 surrounding the drain electrode 470 may be provided on the upper surface of the mold insulating layer 480 and the upper surface of the upper insulating layer 493. The semiconductor device 400 may have a VCT structure including a vertical channel region in which the channel 440 extends in a vertical direction (Z-direction) from the source electrode 420.

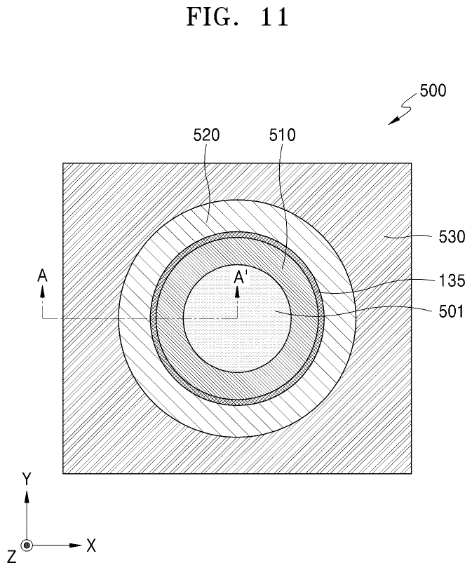

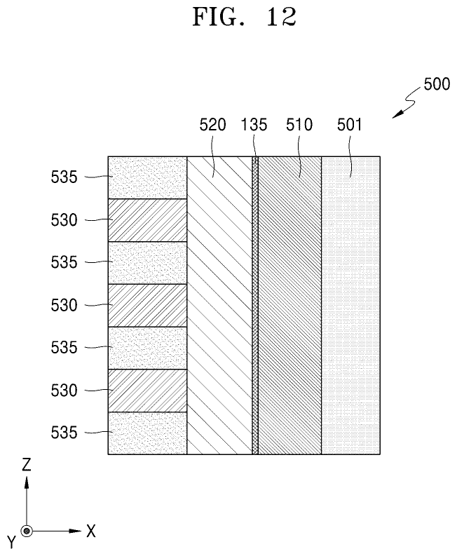

FIGS. 11 and 12 are a horizontal cross-sectional view and a vertical cross-sectional view schematically illustrating a structure of a memory cell string of a memory device 500 according to an example embodiment. Referring to FIG. 11, the memory cell string of the memory device 500 of the example embodiment may include a center filler 501, a channel 510, a ferroelectric layer 520, and a gate electrode 530 that are arranged on an XY plane in a concentric circular shape. The channel 510 may include TeₐO_{b} (a+b=100, 70≤a≤95, and 5≤b≤30). The channel 510 may further include at least one selected from S, Se, In, Sn, Cu, and Ge. The channel 510 may include a single tellurium oxide layer or have a structure in which Te layers and TeO layers are alternately stacked. A reduction-inducing layer 135 may be provided between the channel 510 and the ferroelectric layer 520.

The channel 510 may surround the center filler 501, the ferroelectric layer 520 may surround the channel 510, and the gate electrode 530 may surround the ferroelectric layer 520. The center filler 501 may fill a space formed by an inner wall of the channel 510 and may support the channel 510 and the memory cell string. In some example embodiments, however, the center filler 501 may be omitted. In this case, an empty space may be present in place of the center filler 501.

FIG. 12 is a schematic cross-sectional view taken along line A-A′ of FIG. 11 in a first direction (that is, a Z-direction), from the center of the center filler 501 to the gate electrode 530. Referring to FIG. 12, the memory device 500 may include a plurality of gate electrodes 530, and the gate electrodes 530 may be arranged apart from each other in the first direction. Spacers 535 may be arranged between the gate electrodes 530. That is, the gate electrodes 530 and the spacers 535 may be alternately arranged in the first direction. The memory device 500 may include the channel 510 extending continuously in the first direction and located apart from the gate electrodes 530 and the spacers 535 in a second direction (that is, an X-direction) perpendicular to the first direction, and the ferroelectric layer 520 extending continuously in the first direction between the channel 510 and the gate electrodes 530. In addition, the memory device 500 may further include the center filler 501 that continuously extends in the first direction inside the channel 510. In other words, the ferroelectric layer 520, the channel 510, and the center filler 501 may be sequentially arranged in the second direction from the gate electrodes 530 and the spacers 535. Each of the spacers 535 may

### Include Insulating Silicon Oxide (sio₂), but Is Not Limited Thereto.

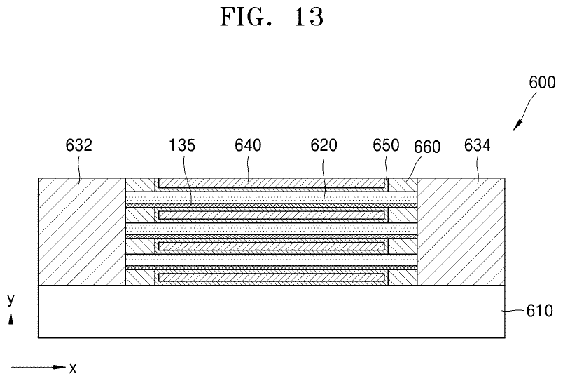

FIG. 13 is a view illustrating a semiconductor device 600 according to an example embodiment. The semiconductor device 600 includes a plurality of channels 620 disposed above a substrate 610, a source electrode 632 and a drain electrode 634 that are in contact with the channels 620, and a plurality of gate electrodes 640 disposed apart from the channels 620. Each of the channels 620 may include TeₐO_{b} (a+b=100, 70≤a≤95, and 5≤b≤30). The channels 620 may further include at least one selected from S, Se, In, Sn, Cu, and Ge. The channels 620 may include a single tellurium oxide layer or may have a structure in which Te layers and TeO layers are alternately stacked.

The substrate 610 may be an insulating substrate, or a semiconductor substrate having an insulating layer formed on a surface thereof. The semiconductor substrate may include, for example, Si, Ge, or SiGe. For example, the substrate 610 may be a silicon substrate having a silicon oxide layer formed on a surface thereof, but is not limited thereto.

The source electrode 632 and the drain electrode 634 may be arranged apart from each other in a first direction (x-direction), and the channels 620 may be arranged apart from each other in a second direction (y-direction) between the source electrode 632 and the drain electrode 634.

The gate electrodes 640 may be apart from each of the channels 620, and ferroelectric layers 650 may be provided between the gate electrodes 640 and the channels 620. For example, the ferroelectric layers 650 may surround at least portions of the gate electrodes 640. For example, the gate electrodes 640 and the channels 620 may be alternately arranged in the second direction (y-direction), and the ferroelectric layers 650 may surround the gate electrodes 640. The ferroelectric layers 650 may insulate the channels 620 and the gate electrodes 640 from each other and may suppress leakage current. Reduction-inducing layers 135 may be provided between the channels 620 and the ferroelectric layers 650. The reduction-inducing layers 135 may be provided on at least one selected from an upper surface and a lower surface of each of the channels 620.

A contact between each of the channels 620 and the source electrode 632 or the drain electrode 634 may have an edge contact structure. For example, both ends of each of the channels 620 may be in contact with the source electrode 632 and the drain electrode 634, respectively.

In addition, each of the gate electrodes 640 may be apart from the source electrode 632 and the drain electrode 634, and spacers 660 may be further provided between the source electrode 632 and the gate electrodes 640 and between the drain electrode 634 and the gate electrodes 640. Because the source electrode 632, the gate electrodes 640, and the drain electrode 634 are arranged in the first direction (x-direction), parasitic capacitance may occur between the source electrode 632 and the gate electrodes 640 and between the drain electrode 634 and the gate electrodes 640. The spacers 660 may include, for example, boron nitride layers to reduce parasitic capacitance. Because the boron nitride layers are not porous and have mechanical strength, the spacers 60 may reliably support the channels 620 disposed above the spacers 660.

The semiconductor device 600 may have a multi-bridge structure in which the channels 620 are each in contact with the source electrode 632 and the drain electrode 634 and are vertically stacked in a direction away from the substrate 610. The channels 620 in the multi-bridge structure may reduce short channel effects and/or a source/drain area, and thus, the semiconductor device 600 may be relatively highly integrated. In addition, uniform source/drain junction capacitance may be maintained regardless of the positions of the channels 620, and thus, the semiconductor device 600 may be used as a relatively high-speed and/or relatively high-reliability device. The semiconductor device 600 may be applied to a GAA transistor. For example, the semiconductor device 600 may be applied as a logic device or a memory device.

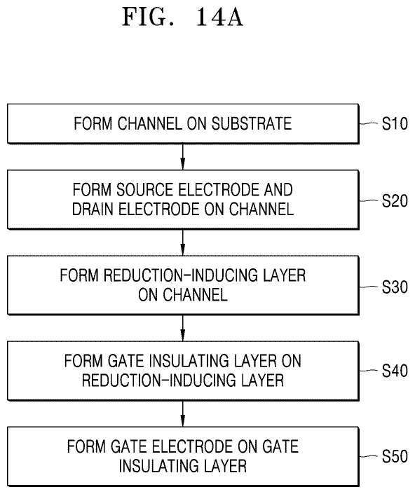

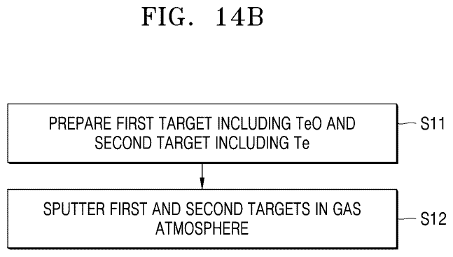

FIG. 14A is a view illustrating a method of manufacturing a semiconductor device according to an example embodiment.

Referring to FIG. 14A, the method of manufacturing a semiconductor device includes forming a channel on a substrate (S10). The channel may be formed by a method such as physical vapor deposition, chemical vapor deposition, or atomic layer deposition. The composition of the channel may be adjusted to TeₐO_{b} (a+b=100, 70≤a≤95, and 5≤b≤30).

A source electrode is formed on a surface of the channel, and a drain electrode is formed on another surface of the channel (S20). Then, a reduction-inducing layer is formed on the channel (S30). It is possible to form the reduction-inducing layer before the channel is formed. A gate insulating layer is formed on the reduction-inducing layer (S40). A gate electrode is formed on the gate insulating layer (S50). In t his manner, a semiconductor device having a p-type channel may be manufactured.

FIG. 14B is a view illustrating an example of a channel forming method.

Forming a channel includes preparing a first target including TeO and a second target including Te in a chamber (S11). Then, the first target and the second target are sputtered in a gas atmosphere (S12). The gas may include, for example, Ar gas. The first and second targets may be prepared in the same chamber, and sputtering may be separately performed on the first and second targets in a gas atmosphere. The deposition amount of O from TeO of the first target may be controlled. In the current example embodiment, a co-sputtering method using multiple targets may be used.

As described above, in a method of manufacturing a semiconductor device according to an example embodiment, a p-type channel including Te and O may be formed using multiple targets.

The semiconductor devices 100, 100A, 300, 300A, 400, 500, and 600 of the example embodiments described above have relatively high on-current and/or relatively high mobility and may thus be applied to various electronic apparatuses such as two-transistor-zero-capacitor (2T0C) dynamic random access memory (DRAM), monolithic 3d (M3D) logic circuits, displays, or gas sensors.

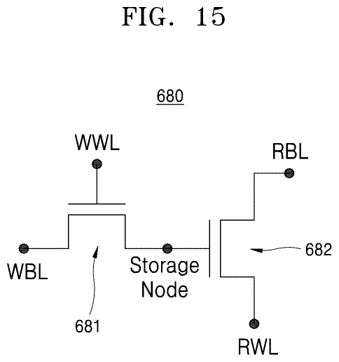

FIG. 15 illustrates an example in which a semiconductor device is applied to a memory device 680, according to an example embodiment. Referring to FIG. 15, the memory device 680 may include a first transistor 681 and a second transistor 682. The semiconductor device 100, 100A, 300, 300A, 400, 500, or 600 described above with reference to FIGS. 1 through 13 may be applied to at least one selected from the first transistor 681 and the second transistor 682. The memory device 680 may be a 2T0C DRAM. In other words, the memory device 680 may have a structure including two transistors and no capacitor. The memory device 680 stores data using the first transistor 681 and the second transistor 682, and is capable of retaining the data even without a capacitor. One of the first transistor 681 and the second transistor 682 may be used as a write transistor, and the other may be used as a read transistor. Hole mobility is an important factor of the read transistor. The channels 120, 320, 440, 510, and 620 of the semiconductor devices 100, 100A, 300, 300A, 400, 500, and 600 of the example embodiments described above have relatively high hole mobility, and the conductivity of the channels 120, 320, 440, 510, and 620 may be increased by adjusting the oxygen content of the channels 120, 320, 440, 510, and 620 to achieve a high on/off ratio. Thus, the semiconductor devices 100, 100A, 300, 300A, 400, 500, and 600 of the example embodiments may be applied to 2T0C DRAM.

In FIG. 15, RWL refers to a read word line, RBL refers to a read bit line, WWL refers to a write word line, and WBL refers to a write bit line.

A unipolar 2T0C DRAM device based on an n-type channel may include an n-type metal oxide semiconductor (MOS) for writing and an n-type MOS for reading. In this case, during write and read operations, voltage drop may occur at a storage node (SN) due to capacitance coupling, resulting in power loss. However, in a 2T0C DRAM device including both an n-type MOS and a p-type MOS, the semiconductor device 100, 100A, 300, 300A, 400, 500, or 600 of the example embodiments described above may be applied to the p-type MOS. In a 2T0C DRAM device based on a p-type channel according to an example embodiment, capacitance coupling may be reduced, enabling read operations without voltage drop.

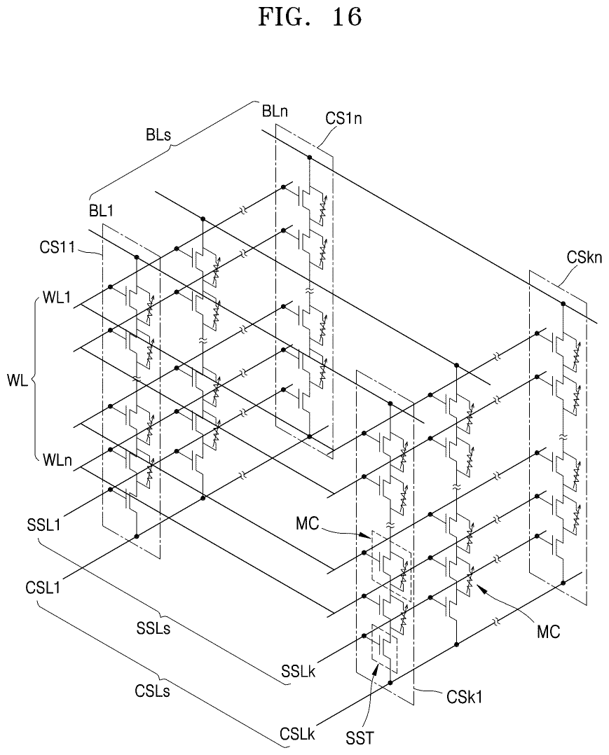

FIG. 16 is a view illustrating an equivalent circuit of a memory device according to an example embodiment.

Referring to FIG. 16, the memory device may include a plurality of memory cell strings CS11 to CSkn. The memory cell strings CS11 to CSkn may be two-dimensionally arranged in a row direction and a column direction, thereby forming rows and columns. Each of the memory cell strings CS11 to CSkn may include a plurality of memory cells MC and a plurality of string selection transistors SST. The memory cells MC and the string selection transistors SST of each of the memory cell strings CS11 to CSkn may be stacked in a height direction. Each of the memory cells MC in each of the memory cell strings CS11 to CSkn may correspond to a circuit in which a transistor and a resistor are connected in parallel to each other. For example, each of the memory cell strings CS11 to CSkn may be the memory cell string illustrated in FIGS. 11 and 12.

The rows of the memory cell strings CS11 to CSkn may be connected to a plurality of string selection lines SSL1 through SSLk, respectively. For example, the string selection transistors SST of the memory cell strings CS11 to CS1n may be commonly connected to the string selection line SSL1. The string selection transistors SST of the memory cell strings CSk1 to CSkn may be commonly connected to the string selection line SSLk.

In addition, the columns of the memory cell strings CS11 to CSkn may be connected to a plurality of bit lines BL1 through BLn, respectively. For example, the memory cells MC and the string selection transistors SST of the memory cell strings CS11 to CSk1 may be commonly connected to the bit line BL1, and the memory cells MC and the string selection transistors SST of the memory cell strings CS1n to CSkn may be commonly connected to the bit line BLn.

In addition, the rows of the memory cell strings CS11 to CSkn may be connected to a plurality of common source lines CSL1 to CSLk, respectively. For example, the string selection transistors SST of the memory cell strings CS11 to CS1n may be commonly connected to the common source line CSL1, and the string selection transistors SST of the memory cell strings CSk1 to CSkn may be commonly connected to the common source line CSLk.

The memory cells MC located at the same height from a substrate (or the string selection transistors SST) may be commonly connected to one word line WL, and the memory cells MC located at different heights from the substrate (or the string selection transistors SST) may be connected to a plurality of word lines WL1 through WLn, respectively.

In this structure, writing and reading may be performed in units of rows of the memory cell strings CS11 to CSkn. For example, the memory cell strings CS11 to CSkn may be selected row by row through the common source lines CSL, and the memory cell strings CS11 to CSkn may be selected row by row through the string selection lines SSL. Furthermore, in a selected row of the cell strings CS11 to CSkn, writing and reading may be performed in units of pages. For example, the term “page” may refer to a row of memory cells MC connected to one word line WL. In a selected row of the memory cell strings CS11 to CSkn, memory cells MC may be selected in units of pages by the word lines WL.

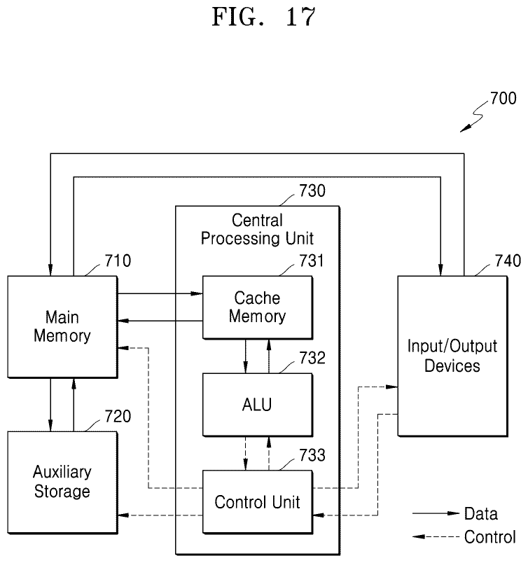

In addition, the semiconductor devices 100, 100A, 300, 300A, 400, 500, and 600 of the example embodiments described above may be used to store data in various electronic apparatuses. FIG. 17 is a conceptual view schematically illustrating a device architecture applicable to electronic apparatuses according to example embodiments. Referring to FIG. 17, an electronic apparatus 700 may include a main memory 710, an auxiliary storage 720, a central processing unit (CPU) 730, and input/output devices 740. The CPU 730 may include a cache memory 731, an arithmetic logic unit (ALU) 732, and a control unit 733. The cache memory 731 may include static random access memory (SRAM). The main memory 710 may include a DRAM device, and the auxiliary storage 720 may include the semiconductor device 100, 100A, 300, 300A, 400, 500, or 600 of the example embodiments described above. In some example embodiment, each of the cache memory 731, the main memory 710, and the auxiliary storage 720 may include the semiconductor device 100, 100A, 300, 300A, 400, 500, or 600 of the example embodiments described above. In some cases, the electronic apparatus 700 may be implemented in the form in which computing unit devices and unit memory unit devices are adjacent to each other on one chip without any distinction between sub-units.

Some of the elements and/or functional blocks disclosed above may be implemented as a processing circuit such as hardware including logic circuits, a hardware/software combination such as processor-executed software, or a combination thereof. For example, the processing circuit may include a CPU, an ALU, a digital signal processor, a microcomputer, a field-programmable gate array (FPGA), a system-on-chip (SoC), a programmable logic unit, a microprocessor, an application-specific integrated circuit (ASIC), or the like. The processing circuit may include electronic components including at least one selected from a transistor, a resistor, and a capacitor. The processing circuit may include electronic components including at least one logic gate selected from an AND gate, an OR gate, a NAND gate, and a NOR gate.

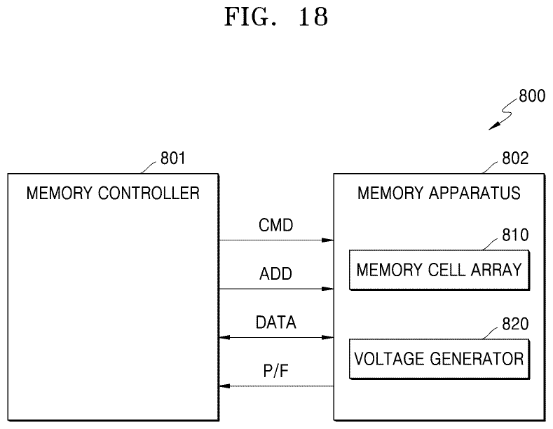

FIG. 18 is a block diagram illustrating a memory system 800 according to an example embodiment.

Referring to FIG. 18, the memory system 800 may include a memory controller 801 and a memory apparatus 802. The memory controller 801 performs a control operation on the memory apparatus 802. For example, the memory controller 801 provides, to the memory apparatus 802, an address ADD and a command CMD for performing programming (or write), read, and/or erase operations on the memory apparatus 802. In addition, data for a programing operation and read data may be transmitted between the memory controller 801 and the memory apparatus 802.

The memory apparatus 802 may include a memory cell array 1610 and a voltage generator 1620. The memory cell array 810 may include a plurality of memory cells and the semiconductor device 100, 100A, 300, 300A, 400, 500, or 600 of the example embodiments described above.

The memory controller 801 may include a processing circuit such as hardware including a logic circuit, a hardware/software combination such as processor-executed software, or a combination thereof. Examples of the processing circuit may include a CPU, an ALU, a digital signal processor, a microcomputer, an FPGA, an SoC, a programmable logic unit, a microprocessor, and an ASIC, but are not limited thereto. The memory controller 801 may operate in response to a request from a host (not shown), and may be configured to change into a special purpose controller by accessing to the memory apparatus 802 and controlling a control operation (for example, a write/read operation) discussed above. The memory controller 801 may generate an address ADD and a command CMD for performing a programming/read/erase operation on the memory cell array 810. In addition, in response to a command from the memory controller 801, the voltage generator 1620 (for example, a power circuit) may generate a voltage control signal for controlling a voltage level of a word line to program data in the memory cell array 810 or read data from the memory cell array 810.

In addition, the memory controller 801 may perform a determination operation on data read from the memory apparatus 802. For example, the number of on-cells and/or the number of off-cells may be determined based on data read from memory cells. The memory apparatus 802 may provide a pass/fail signal P/F to the memory controller 801 according to results of data reading. The memory controller 801 may control write and read operations of the memory cell array 1610 with reference to the pass/fail signal P/F.

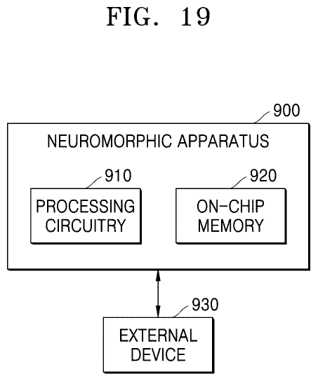

FIG. 19 is a block diagram illustrating a neuromorphic apparatus 900 and an external device 930 connected thereto, according to an example embodiment.

Referring to FIG. 19, the neuromorphic apparatus 900 may include processing circuitry 910 and/or an on-chip memory 920. The on-chip memory 920 may include the semiconductor device 100, 100A, 300, 300A, 400, 500, or 600 of the example embodiments described above.

In some example embodiments, the processing circuitry 910 may be configured to control a function for driving the neuromorphic apparatus 900. For example, the processing circuitry 910 may be configured to control the neuromorphic apparatus 900 by executing a program stored in the on-chip memory 920. In some example embodiments, the processing circuitry 910 may include hardware such as a logic circuit, a hardware/software combination such as a processor configured to execute software, or a combination thereof. For example, the processor may include a CPU, a graphics processing unit (GPU), an application processor (AP) included in the neuromorphic apparatus 900, an ALU, a digital signal processor, a microcomputer, a FPGA, a SoC, a programmable logic unit, a microprocessor, an ASIC, or the like, but is not limited thereto. In some example embodiments, the processing circuitry 910 may read/write various data with respect to an external device 930, and/or may be configured to execute the neuromorphic apparatus 900 using the read/written data. In s ome example embodiments, the external device 930 may include an external memory and/or a sensor array having an image sensor (for example, a complementary metal-oxide-semiconductor (CMOS) image sensor circuit).

In some example embodiments, the neuromorphic apparatus 900 may be applied to a machine learning system. The machine learning system may use various artificial neural network organizing and processing models such as a convolutional neural network (CNN), a deconvolutional neural network, a recurrent neural network (RNN) including a long short-term memory (LSTM) unit and/or a gated recurrent unit (GRU), a stacked neural network (SNN), a state-space dynamic neural network (SSDNN), a deep belief network (DBN), a generative adversarial network (GAN), and/or a restricted Boltzmann machine (RBM).

Alternatively or additionally, the machine learning system may include other forms of machine learning models, for example, linear and/or logistic regression, statistical clustering, Bayesian classification, decision tree, dimensionality reduction such as principal component analysis, an expert system, and/or a combination thereof including ensembles such as random forests. These machine learning models may be used to provide various services and/or applications. For example, an image classification service, a user authentication service based on biometrics or biometric data, an advanced driver assistance system (ADAS) service, a voice assistant service, or an automatic speech recognition (ASR) service may be executed by an electronic apparatus.

The semiconductor devices 100, 100A, 300, 300A, 400, 500, and 600 of the example embodiments described above may be used in transistors, photovoltaic cells, thermoelectric devices, light-emitting diodes, displays, or the like, and may also be used in DRAM, flash memory, CMOS image sensors, or the like.

As described above, the semiconductor devices 100, 100A, 300, 300A, 400, 500, and 600 of the example embodiments described above have a structure in which a reduction-inducing layer is provided on a channel for controlling the oxygen content of the channel, thereby implementing a p-type channel. Therefore, the semiconductor devices 100, 100A, 300, 300A, 400, 500, and 600 of the example embodiments described above may be applied to various devices such as logic circuit devices or 2T0C DRAM.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel comprising a first surface and a second surface opposing the first surface;
a source electrode electrically connected to the channel;
a drain electrode electrically connected to the channel and being apart from the source electrode;
a gate insulating layer above the channel;
a gate electrode on the gate insulating layer; and
a reduction-inducing layer on at least one selected from the first surface and the second surface of the channel,
wherein the reduction-inducing layer comprises M or MO, and M comprises at least one selected from Ti, Sc, Ce, Si, and V.

2. The semiconductor device of claim 1, wherein the channel is a p-type channel.

3. The semiconductor device of claim 1, wherein the channel comprises tellurium oxide.

4. The semiconductor device of claim 3, wherein the channel further comprises at least one selected from S, Se, In, Sn, Cu, and Ge.

5. The semiconductor device of claim 3, wherein the channel comprises TeₐO_{b}, where a+b=100, 70≤a≤95, and 5≤b≤30.

6. The semiconductor device of claim 1, wherein the channel is in an oxygen-deficient state.

7. The semiconductor device of claim 1, wherein a first direction defined from the source electrode toward the drain electrode is a vertical direction of the semiconductor device, and length directions of the channel, the gate insulating layer, and the gate electrode are parallel to the first direction.

8. The semiconductor device of claim 1, wherein the channel further comprises
a bottom portion in contact with the source electrode,
a first vertical extension portion extending from an end of the bottom portion in a direction perpendicular to the source electrode, and
a second vertical extension portion extending from another end of the bottom portion in the direction perpendicular to the source electrode.

9. The semiconductor device of claim 1, wherein
the channel, the gate insulating layer, and the gate electrode are arranged in a concentric shape,
the gate electrode comprises a first gate electrode and a second gate electrode that are apart from each other, and
a spacer is between the first gate electrode and the second gate electrode.

10. The semiconductor device of claim 1, wherein the channel comprises a plurality of channels and has a multi-bridge structure in which the plurality of channels are each in contact with the source electrode and the drain electrode and are stacked apart from each other in a direction away from a substrate.

11. An electronic apparatus comprising:
a host;
a memory device comprising at least one semiconductor device; and
a memory controller configured to control the memory device in response to a request from the host for at least one selected from a first operation of reading data from the memory device and a second operation of writing data to the memory device,
wherein the at least one semiconductor device comprises
a channel comprising a first surface and a second surface opposing the first surface,
a source electrode electrically connected to the channel,
a drain electrode electrically connected to the channel and being apart from the source electrode,
a gate insulating layer above the channel,
a gate electrode on the gate insulating layer, and
a reduction-inducing layer on at least one selected from the first surface and the second surface of the channel, and
wherein the reduction-inducing layer comprises M or MO, and M comprises at least one selected from Ti, Sc, Ce, Si, or V.

12. The electronic apparatus of claim 11, wherein the channel is a p-type channel.

13. The electronic apparatus of claim 11, wherein the channel comprises tellurium oxide.

14. The electronic apparatus of claim 13, wherein the channel further comprises at least one selected from S, Se, In, Sn, Cu, and Ge.

15. The electronic apparatus of claim 13, wherein the channel comprises TeₐO_{b}, where a+b=100, 70≤a≤95, and 5≤b≤30.

16. The electronic apparatus of claim 11, wherein the channel is in an oxygen-deficient state.

17. The electronic apparatus of claim 11, wherein the memory device comprises a dynamic random access memory (DRAM) device having a two-transistor-zero-capacitor (2T0C) structure.

18. A method of manufacturing a semiconductor device, the method comprising:
forming a channel on a substrate;
forming a source electrode and a drain electrode apart from each other on the channel;
forming a reduction-inducing layer on the channel;
forming a gate insulating layer on the reduction-inducing layer; and
forming a gate electrode on the gate insulating layer,
wherein the reduction-inducing layer comprises M or MO, and the M comprises at least one selected from Ti, Sc, Ce, Si, and V.

19. The method of claim 18, wherein the channel comprises TeₐO_{b}, where a+b=100, 70≤a≤95, and 5≤b≤30.

20. The method of claim 19, wherein the forming of the channel comprises:
preparing a first target comprising TeO and a second target comprising Te; and
sputtering the first target and the second target in a gas atmosphere.
